(19) United States
(12) Patent Application Publication
(10) Pub. No.: US 2023/0029098 A1
(43) Pub. Date: Jan. 26, 2023

(54) SEMICONDUCTOR PACKAGE

(71) Applicant: SAMSUNG ELECTRONICS CO., LTD., Suwon-si (KR)

(72) Inventors: Taehyeong KIM, Suwon-si (KR); Hyeonjun SONG, Hwaseong-si (KR); Jungseok AHN, Seoul (KR)

(21) Appl. No.: 17/730,550

(22) Filed: Apr. 27, 2022

(30) Foreign Application Priority Data
Jul. 26, 2021 (KR) 10-2021-0098116

(51) Int. Cl. H01L 25/065; H01L 23/00; H01L 23/48

(52) U.S. Cl. CPC H01L 25/0657; H01L 24/16; H01L 24/73; H01L 23/481; H01L 2224/16145; H01L 2224/73204; H01L 2225/06513; H01L 2224/16227

(57) ABSTRACT

A semiconductor package including a first substrate including a first bump pad and a filling compensation film (FCF) around the first bump pad; a second substrate facing the first substrate and including a second bump pad; a bump structure (BS) in contact with the first bump pad and the second bump pad; and a non-conductive film (NCF) surrounding the BS and between the first substrate and the second substrate, wherein the NCF covers an upper surface and an edge of the FCF.

### CROSS-REFERENCE TO RELATED APPLICATION

This application is based on and claims priority under 35 U.S.C. § 119 to Korean Patent Application No. 10-2021-0098116, filed on Jul. 26, 2021, in the Korean Intellectual Property Office, the disclosure of which is incorporated by reference herein in its entirety.

### BACKGROUND

### 1. Field

Embodiments relate to a semiconductor package.

### 2. Description of the Related Art

Recently, in the electronic products market, demand for portable devices has rapidly increased, and accordingly, electronic components, e.g., semiconductor chips, mounted on these products may be miniaturized and light in weight. In order to realize miniaturization and weight reduction of these electronic components, semiconductor package technology for integrating a plurality of semiconductor chips constituting components into one package, as well as technology for reducing an individual size of the mounted components has been considered.

### SUMMARY

The embodiments may be realized by providing a semiconductor package including a first substrate including a first bump pad and a filling compensation film (FCF) around the first bump pad; a second substrate facing the first substrate and including a second bump pad; a bump structure (BS) in contact with the first bump pad and the second bump pad; and a non-conductive film (NCF) surrounding the BS and between the first substrate and the second substrate, wherein the NCF covers an upper surface and an edge of the FCF.

The embodiments may be realized by providing a semiconductor package including a base substrate; semiconductor chips mounted on the base substrate, stacked in a direction perpendicular to an upper surface of the base substrate, and including a through-electrode therein; and a connection layer between the base substrate and one of the semiconductor chips and between adjacent ones of the semiconductor chips, the connection layer including a filling compensation film (FCF) and a non-conductive film (NCF) covering the FCF.

The embodiments may be realized by providing a semiconductor package including a base substrate; a first semiconductor chip including a first bump pad mounted on the base substrate and a filling compensation film (FCF) around the first bump pad, the first bump pad being connected to a first through-electrode; a second semiconductor chip stacked on the first semiconductor chip and including a second bump pad connected to a second through-electrode; a bump structure (BS) in contact with the first bump pad and the second bump pad; a non-conductive film (NCF) surrounding the BS and between the first semiconductor chip and the second semiconductor chip; and a molding member covering the base substrate, the first semiconductor chip, and the second semiconductor chip, wherein the NCF covers an upper surface and an edge of the FCF.

### BRIEF DESCRIPTION OF THE DRAWINGS

Features will be apparent to those of skill in the art by describing in detail exemplary embodiments with reference to the attached drawings in which:

FIG. 1A is a cross-sectional view of main components of a semiconductor package according to an embodiment;

FIG. 1B is an enlarged cross-sectional view of region BB of FIG. 1A;

FIG. 2A is a cross-sectional view of main components of a semiconductor package according to another embodiment;

FIG. 2B is an enlarged cross-sectional view of region BB of FIG. 2A;

FIGS. 3 to 5 are cross-sectional views of main components of a semiconductor package according to another;

FIG. 6 is a flowchart of a method of manufacturing a semiconductor package according to an embodiment;

FIGS. 7A to 7F are cross-sectional views of stages in a method of manufacturing a semiconductor package according to an embodiment; and

FIG. 8 is a diagram schematically illustrating a configuration of a semiconductor package according to embodiments.

### DETAILED DESCRIPTION

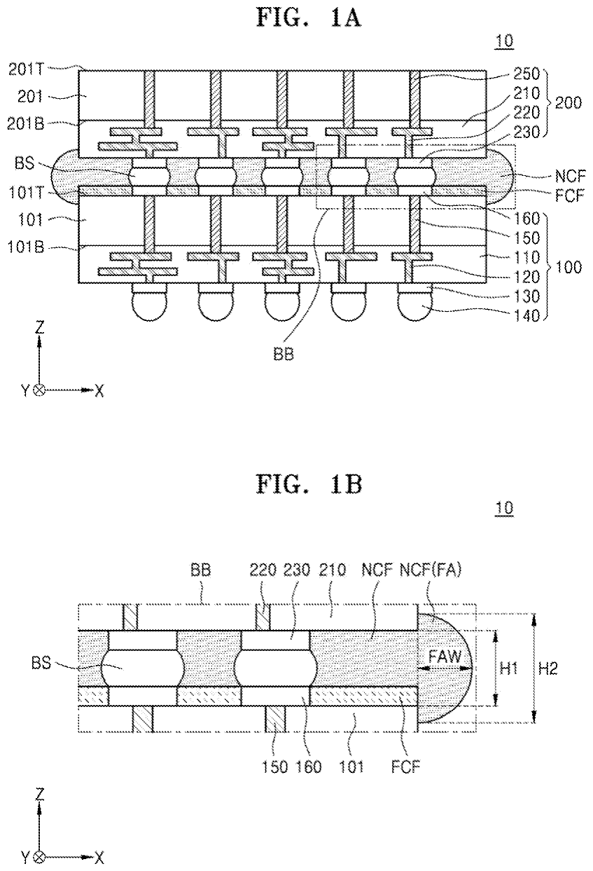

FIG. 1A is a cross-sectional view of main components of a semiconductor package 10 according to an example embodiment, and FIG. 1B is an enlarged cross-sectional view of region BB of FIG. 1A.

Referring to FIGS. 1A and 1B together, the semiconductor package 10 may include a first semiconductor chip 100, a second semiconductor chip 200, a non-conductive film (NCF) bonding the first semiconductor chip 100 to the second semiconductor chip 200, and a filling compensation film (FCF) below the NCF.

Each of the first and second semiconductor chips 100 and 200 included in the semiconductor package 10 of the present embodiment may be a memory chip or a logic chip. In an implementation, both the first and second semiconductor chips 100 and 200 may be the same type of memory chips or one of the first and second semiconductor chips 100 and 200 may be a memory chip and the other may be a logic chip.

The memory chip may be, e.g., a volatile memory chip such as dynamic random access memory (DRAM) or static random access memory (SRAM) or a non-volatile memory chip such as phase-change random access memory (PRAM), magnetoresistive random access memory (MRAM), ferroelectric random access memory (FeRAM), or resistive random access memory (RRAM). In an implementation, the logic chip may be, e.g., a microprocessor, an analog device, or a digital signal processor.

The first semiconductor chip 100 may include a first substrate 101, a first semiconductor device layer 110, a first interconnection layer 120, a first connection pad 130, a first connection terminal 140, a first through-electrode 150, and a first bump pad 160.

The first substrate 101 may be a semiconductor substrate and may include an upper surface 101T and a lower surface 101B opposite to each other. Here, the upper surface 101T may be referred to as an inactive surface, and the lower surface 101B may be referred to as an active surface. The first substrate 101 may include the first semiconductor device layer 110 adjacent to the lower surface 101B and the first through-electrode 150 penetrating through the first substrate 101.

The first substrate 101 may be, e.g., a silicon (Si) wafer including crystalline silicon, polycrystalline silicon, or amorphous silicon. In an implementation, the first substrate 101 may include a semiconductor element such as germanium (Ge), or a compound semiconductor, e.g., silicon carbide (SiC), gallium arsenide (GaAs), indium arsenide (InAs), or indium phosphide (InP). As used herein, the term “or” is not an exclusive term, e.g., “A or B” would include A, B, or A and B.

In an implementation, the first substrate 101 may have a silicon-on-insulator (SOI) structure. In an implementation, the first substrate 101 may include a buried oxide layer (BOX). In an implementation, the first substrate 101 may include a conductive region, e.g., a well doped with an impurity or a structure doped with an impurity. In an implementation, the first substrate 101 may have various device isolation structures such as a shallow trench isolation (STI) structure.

The first semiconductor device layer 110 may include the first interconnection layer 120 for connecting a plurality of semiconductor devices to other interconnections in the first substrate 101. The first interconnection layer 120 may include a metal interconnection layer and a via plug. In an implementation, the first interconnection layer 120 may have a multilayer structure in which two or more metal interconnection layers and/or two or more via plugs are alternately stacked.

The first connection pad 130 may be below the first semiconductor device layer 110, and may be electrically connected to the first interconnection layer 120 inside the first semiconductor device layer 110. The first connection pad 130 may be electrically connected to the first through-electrode 150 through the first interconnection layer 120. In an implementation, the first connection pad 130 may include, e.g., aluminum (Al), copper (Cu), nickel (Ni), tungsten (W), platinum (Pt), or gold (Au).

The first connection terminal 140 may directly contact the first connection pad 130. The first connection terminal 140 may electrically connect the semiconductor package 10 to an external base substrate. The first semiconductor chip 100 may receive at least one of a control signal, a power signal, and a ground signal for an operation thereof through the first connection terminal 140, may receive a data signal to be stored therein, or may provide data stored therein to the outside. In an implementation, the first connection terminal 140 may include a pillar structure, a ball structure, or a solder layer.

The first through-electrode 150 may penetrate through the first substrate 101, may extend from the upper surface 101T of the first substrate 101 toward the lower surface 101B thereof, and may be connected to the first interconnection layer 120 inside the first semiconductor device layer 110. The first connection pad 130 may be electrically connected to the first through-electrode 150 through the first interconnection layer 120. At least a portion of the first through-electrode 150 may have a pillar shape. In an implementation, the first through-electrode 150 may be a through-silicon via (TSV).

The first bump pad 160 may be on the upper surface 101T of the first substrate 101 and may contact the first through-electrode 150. The first bump pad 160 may be electrically connected to the first interconnection layer 120 inside the first semiconductor device layer 110 through the first through-electrode 150. In an implementation, the first bump pad 160 may include, e.g., aluminum (Al), copper (Cu), nickel (Ni), tungsten (W), platinum (Pt), or gold (Au).

The second semiconductor chip 200 may be positioned such that a lower surface 201B of a second substrate 201 of the second semiconductor chip 200 faces the upper surface 101T of the first substrate 101 of the first semiconductor chip 100. The second semiconductor chip 200 may be electrically connected to the first semiconductor chip 100 through a bump structure (BS) between the first semiconductor chip 100 and the second semiconductor chip 200.

The second semiconductor chip 200 may include the second substrate 201, a second semiconductor device layer 210, a second interconnection layer 220, a second bump pad 230, and a second through-electrode 250. The second semiconductor chip 200 may have characteristics that are the same as or similar to the first semiconductor chip 100, and thus, for convenience of description, differences thereof from the first semiconductor chip 100 are mainly described.

The second substrate 201, as a semiconductor substrate, may include an upper surface 201T and a lower surface 201B opposite to each other. Here, the lower surface 201B may be referred to as an active surface, and the upper surface 201T may be referred to as an inactive surface.

The second semiconductor device layer 210 may be below the lower surface 201B of the second substrate 201. The second bump pad 230 may be on the second semiconductor device layer 210, and may be electrically connected to the second interconnection layer 220 inside the second semiconductor device layer 210. The second bump pad 230 may be electrically connected to the second through-electrode 250 through the second interconnection layer 220. The second bump pad 230 may be formed of substantially the same material as that of the first bump pad 160.

The BS may contact each of the first bump pad 160 and the second bump pad 230 and electrically connect them to each other. Through the BS, the second semiconductor chip 200 may receive at least one of a control signal, a power signal, and a ground signal for an operation thereof from the outside, may receive a data signal to be stored therein, or may provide data stored therein to the outside. In an implementation, the BS may include a pillar structure, a ball structure, or a solder layer.

An adhesive layer may be between the upper surface 101T of the first substrate 101 and the lower surface 201B of the second substrate 201 to attach the second semiconductor chip 200 to the first semiconductor chip 100. The adhesive layer may be in direct contact with the first semiconductor chip 100 and the second semiconductor chip 200 and may surround the BS. In an implementation, the adhesive layer may be formed of a non-conductive film (NCF).

The NCF may include, e.g., an adhesive resin and a flux. This is described in detail as follows.

The adhesive resin may adhere the first and second semiconductor chips 100 and 200 to each other. The adhesive resin may be a thermosetting resin. The adhesive resin may include, e.g., a bisphenol epoxy resin, a novolac epoxy resin, a phenol resin, a urea resin, a melamine resin, an unsaturated polyester resin, or a resorcinol resin.

The flux may be used for soldering for electrical bonding between the first and second semiconductor chips 100 and 200 during a manufacturing process of the semiconductor package 10. The flux may help improve spreadability or wettability of a solder and may be previously applied to a portion on which the solder is to be applied, or may be included in the NCF. In an implementation, the flux may be, e.g., a resin flux, an organic flux, or an inorganic flux. In an implementation, the resin flux may be used in electronic products. A main material of the resin flux may include, e.g., rosin, modified rosin, or synthetic resin. The flux may be, e.g., a rosin activated (RA) flux, a rosin mildly activated (RMA) flux, or a rosin (R) flux, according to the degree of activation.

In an implementation, in the semiconductor package 10, an FCF may be below the NCF. In an implementation, the FCF may be on the NCF. In an implementation, the FCF may be below or on the NCF. In an implementation, an edge of the FCF may be on the same plane in a vertical direction (a Z direction) as an edge of each of the first substrate 101 and the second substrate 201 (e.g., may be vertically aligned or coplanar).

The FCF may expose the first bump pad 160 and may contact a side surface of the first bump pad 160. The FCF may be formed of an insulating material. In an implementation, the FCF may be formed of, e.g., a polymer, benzocyclobutene, or a resin, (e.g., a photosensitive polyimide). In an implementation, the FCF may be formed of, e.g., silicon oxide or silicon nitride.

In an implementation, a distance in the Z direction or height H1 between the first and second semiconductor chips 100 and 200 may be less than a thickness of the NCF in an initial state, due to characteristics of the manufacturing process of the semiconductor package 10, the amount of the NCF corresponding to a difference in thickness may overflow in a peripheral direction of the first and second semiconductor chips 100 and 200, which may form a fillet area FA of the NCF. A height H2 of the fillet area FA of the NCF may be greater than the height H1 between the first and second semiconductor chips 100 and 200.

In an implementation, a width FAW of the fillet area FA of the NCF measured in a horizontal direction (an X direction) from the (e.g., outer) edge of the FCF may be about 100 μm or less. In an implementation, the NCF may be in contact with an upper surface and a side surface of the FCF.

The semiconductor package 10 used in electronic products may have high performance and a large capacity along with miniaturization and weight reduction. In order to realize this, the first and second semiconductor chips 100 and 200 may include the through-electrode 150 and the semiconductor package 10 in which the first and second semiconductor chips 100 and 200 are stacked.

In order to reduce a size and weight of the first and second semiconductor chips 100 and 200 including the through-electrode 150, and the semiconductor package 10 in which the first and second semiconductor chips 100 and 200 are stacked, the thickness of the first and second semiconductor chips 100 and 200 may be reduced structurally. In an implementation, to help ensure uniform adhesion of the first and second semiconductor chips 100 and 200, bonding of fine-sized bump structures, solder wettability, electrical reliability, structural reliability, and the like, the NCF may be used as an adhesive layer, which is an interlayer bonding material of the semiconductor package 10 in the process of stacking the first and second semiconductor chips 100 and 200.

During the manufacturing process of the semiconductor package 10, after the first and second semiconductor chips 100 and 200 are bonded to each other, if the amount of the fillet area FA of the NCF overflowing to the periphery of the first and second semiconductor chips 100 and 200 were to be excessive, various issues could arise in a subsequent process, and could ultimately cause deterioration of quality of the semiconductor package 10.

Therefore, in order to reduce the amount of the fillet area FA of the NCF that overflows, the thickness of the NCF may be reduced or pressure applied to the second substrate 201 may be reduced in performing the manufacturing process of the semiconductor package 10.

In this case, however, the reduction in only the thickness of the NCF compared to the height of the BS or the reduction in only the pressure applied to the second substrate 201 could cause unfilling of the NCF. Due to this, a phenomenon in which the first and second semiconductor chips 100 and 200 adjacent to each other are not evenly bonded or a void is formed between the first and second semiconductor chips 100 and 200 could occur.

In order to compensate for this phenomenon, in the semiconductor package 10 according to an embodiment, the FCF formed of a material having less fluidity than that of the NCF may be in the region in which the unfilling may occur, thereby significantly reducing the amount of the fillet area FA of the NCF.

In an implementation, even if the pressure applied to the second substrate 201 were reduced and the NCF were less compressed, unfilling may not occur and the fillet area FA may protrude less to the periphery of the first and second semiconductor chips 100 and 200. Accordingly, a phenomenon in which the NCF excessively overflows may be prevented, and at the same time, a phenomenon in which the NCF is not filled may be prevented.

In an implementation, the semiconductor package 10 may have an effect of providing high product reliability and high production efficiency.

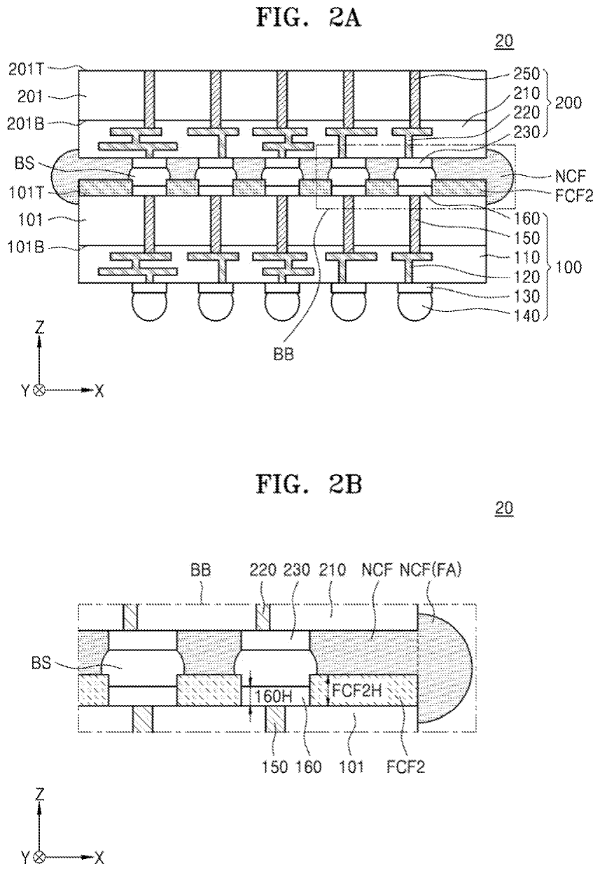

FIG. 2A is a cross-sectional view of main components of a semiconductor package 20 according to another embodiment, and FIG. 2B is an enlarged cross-sectional view of region BB of FIG. 2A.

Most of the components constituting the semiconductor package 20 and materials constituting the components described below are substantially the same as or similar to those described above with reference to FIGS. 1A and 1B. Therefore, for convenience of description, differences from the semiconductor package 10 described above are mainly described.

Referring to FIGS. 2A and 2B together, the semiconductor package 20 may include a first semiconductor chip 100, a second semiconductor chip 200, an NCF bonding the first and second semiconductor chips 100 and 200 to each other, and a filling compensation film FCF2 below the NCF.

A BS may be in contact with each of the first bump pad 160 and the second bump pad 230 to electrically connect the first bump pad 160 to the second bump pad 230. Through the BS, the second semiconductor chip 200 may receive at least one of a control signal, a power signal, and a ground signal for an operation thereof from the outside, may receive a data signal to be stored therein from the outside, or may provide data stored therein to the outside. In an implementation, the BS may have a pillar structure, a ball structure, or a solder layer.

The FCF2 may be formed of an insulating material. In an implementation, the FCF2 may be formed of, e.g., a polymer, benzocyclobutene, or a resin (e.g., a photosensitive polyimide). In an implementation, the FCF2 may be formed of silicon oxide or silicon nitride.

In the semiconductor package 20 of the present embodiment, the FCF2 may expose the first bump pad 160 and may be in contact with a side surface of the first bump pad 160. In an implementation, a level of an upper surface of the FCF2 may be higher than a level of an upper surface of the first bump pad 160 (e.g., a distance from the first substrate 101 to the upper surface of the FCF2 in the Z direction may be greater than a distance from the first substrate 101 to the upper surface of the first bump pad 160 in the Z direction).

In an implementation, a thickness FCF2H of the FCF2 may be greater than a thickness 160H of the first bump pad 160 (e.g., as measured in the Z direction). first substrate, a lower portion of the BS may contact the upper surface of the first bump pad 160 and a sidewall of the FCF2.

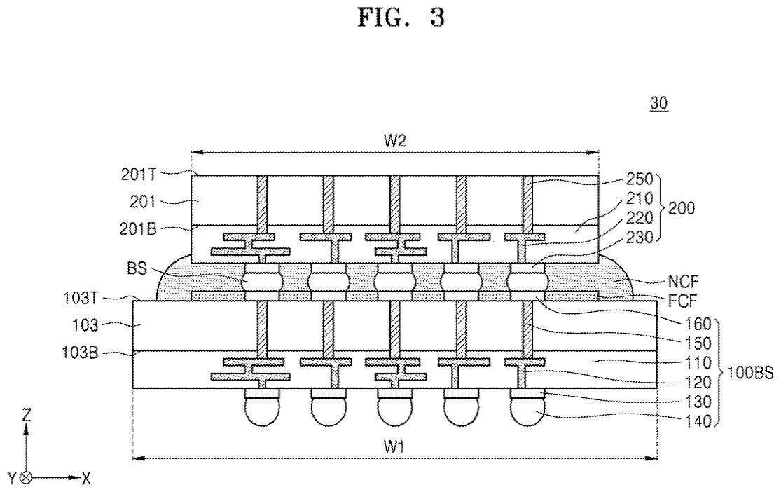

FIGS. 3 to 5 are cross-sectional views of main components of semiconductor packages 30, 40, and 50 according to other embodiments.

Most of the components constituting the semiconductor packages 30, 40, and 50 and materials constituting the components described below are substantially the same as or similar to those described above with reference to FIGS. 1A and 1B. Therefore, for convenience of description, differences from the semiconductor package 10 described above are mainly described.

Referring to FIG. 3, the semiconductor package 30 may include a first base substrate 100BS, a second semiconductor chip 200, an NCF bonding the first base substrate 100BS to the second semiconductor chip 200, and an FCF below the NCF.

The first base substrate 100BS may be formed based on or may be, e.g., a printed circuit board (PCB), a wafer substrate, a ceramic substrate, a glass substrate, an interposer, or the like. In an implementation, the first base substrate 100BS may constitute or may be a buffer chip.

In an implementation, when the first base substrate 100BS is a PCB, the first base substrate 100BS may be formed of, e.g., a phenol resin, an epoxy resin, or a polyimide.

In an implementation, when the first base substrate 100BS is an interposer, the interposer may further include a circuit region, and the circuit region may include a buffer circuit for controlling capacitance loading of the second semiconductor chip 200. In an implementation, a semiconductor integrated circuit (IC) including a transistor, a diode, a capacitor, or a resistor may be formed in the circuit region. In an implementation, the circuit region may be omitted.

In the semiconductor package 30 of the present embodiment, a first substrate 103 constituting the first base substrate 100BS may have a first width W1 in the horizontal direction (the X direction), and a second substrate 201 constituting the second semiconductor chip 200 may have a second width W2 that is less than the first width W1. In an implementation, the NCF may cover a portion of an upper surface 103T of the first substrate 103.

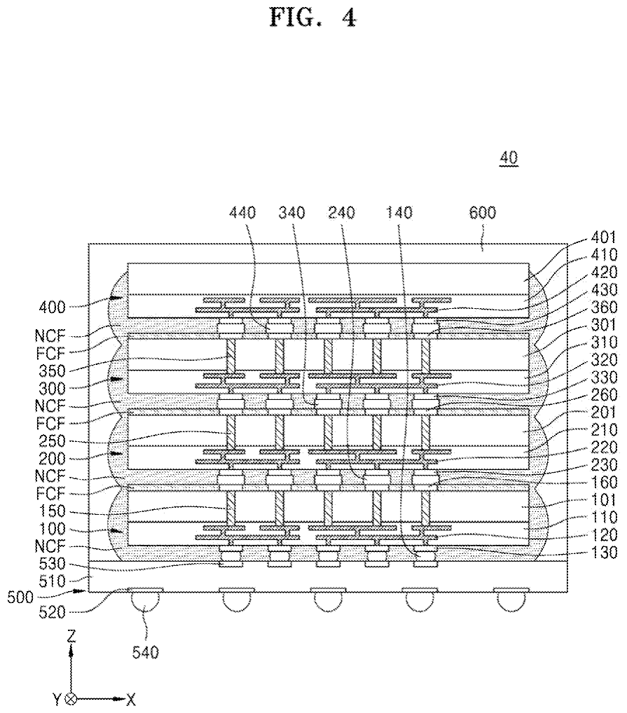

Referring to FIG. 4, the semiconductor package 40 may include a first semiconductor chip 100, a second semiconductor chip 200, a third semiconductor chip 300, and a fourth semiconductor chip 400 stacked on a base substrate 500 in the vertical direction (the Z direction).

The first to fourth semiconductor chips 100, 200, 300, and 400 may be electrically connected to each other through first to fourth connection terminals 140, 240, 340 and 440 or may be electrically connected to the base substrate 500. In addition, each of the first to fourth semiconductor chips 100, 200, 300, and 400 may be attached to the base substrate 500 by an NCF.

The first to fourth semiconductor chips 100, 200, 300, and 400 may be memory chips or logic chips. In an implementation, the first to fourth semiconductor chips 100, 200, 300, and 400 may all be the same type of memory chips, or some of the first to fourth semiconductor chips 100, 200, 300 and 400 may be memory chips and the others may be logic chips. In an implementation, the first to fourth semiconductor chips 100, 200, 300, and 400 may be high bandwidth memory (HBM) chips.

In an implementation, as illustrated in the drawings, the first to fourth semiconductor chips 100, 200, 300, and 400 may be stacked. In an implementation, two or more semiconductor chips may be stacked in the semiconductor package 40.

The first semiconductor chip 100 may include a first substrate 101, a first semiconductor device layer 110, a first interconnection layer 120, a first connection pad 130, the first connection terminal 140, a first through-electrode 150, and a first bump pad 160.

The second semiconductor chip 200 may include a second substrate 201, a second semiconductor device layer 210, a second interconnection layer 220, a second lower bump pad 230, the second connection terminal 240, a second through-electrode 250, and a second upper bump pad 260.

The second semiconductor chip 200 may be mounted on an upper surface of the first semiconductor chip 100. The second semiconductor chip 200 may be electrically connected to the first semiconductor chip 100 through the second connection terminal 240 between the first semiconductor chip 100 and the second semiconductor chip 200.

In an implementation, an NCF and an FCF may be between an upper surface of the first semiconductor chip 100 and a lower surface of the second semiconductor chip 200 to attach the second semiconductor chip 200 to the first semiconductor chip 100.

The third semiconductor chip 300 may include a third substrate 301, a third semiconductor device layer 310, a third interconnection layer 320, a third lower bump pad 330, the third connection terminal 340, a third through-electrode 350, and a third upper bump pad 360.

The fourth semiconductor chip 400 may include a fourth substrate 401, a fourth semiconductor device layer 410, a fourth interconnection layer 420, a fourth lower bump pad 430, and the fourth connection terminal 440. Unlike the first to third semiconductor chips 100, 200, and 300, the fourth semiconductor chip 400 may not include a through-electrode and an upper bump pad.

The third semiconductor chip 300 may be mounted on an upper surface of the second semiconductor chip 200, and the fourth semiconductor chip 400 may be mounted on an upper surface of the third semiconductor chip 300. A third connection terminal 340 and an NCF and an FCF surrounding a side surface of the third connection terminal 340 may be between the second semiconductor chip 200 and the third semiconductor chip 300. Similarly, a fourth connection terminal 440 and an NCF and an FCF surrounding a side surface of the fourth connection terminal 440 may be between the third semiconductor chip 300 and the fourth semiconductor chip 400.

In an implementation, when the base substrate 500 is a PCB, the base substrate 500 may include a substrate body portion 510, a lower surface pad 520, an upper surface pad 530, and a solder resist layer between a lower surface and an upper surface of the substrate body portion 510. An internal interconnection electrically connecting the lower surface pad 520 to the upper surface pad 530 may be inside the substrate body portion 510. The lower surface pad 520 and the upper surface pad 530 may be portions, of a circuit interconnection patterned on the lower surface and upper surface of the substrate body portion 510, exposed by the solder resist layer.

In an implementation, when the base substrate 500 is an interposer, the base substrate 500 may include the substrate body portion 510, which may be formed of a semiconductor material, and the lower surface pad 520 and the upper surface pad 530 respectively on the lower surface and the upper surface of the substrate body portion 510. The substrate body portion 510 may be formed from, e.g., a semiconductor wafer. In an implementation, an internal interconnection may be on the lower surface, the upper surface, or inside the substrate body portion 510. In an implementation, a through-via electrically connecting the lower surface pad 520 to the upper surface pad 530 may be inside the substrate body portion 510.

An external connection terminal 540 may be attached to a lower surface of the base substrate 500. The external connection terminal 540 may be attached to the lower surface pad 520. The external connection terminal 540 may be, e.g., a solder ball or a bump. The external connection terminal 540 may electrically connect the semiconductor package 40 to an external device.

In an implementation, an NCF may be between the base substrate 500 and the first semiconductor chip 100. The NCF may be between the base substrate 500 and the first semiconductor chip 100 and may surround a side surface of the first connection terminal 140.

A molding member 600 may surround the first to fourth semiconductor chips 100, 200, 300, and 400 on the base substrate 500. The molding member 600 may surround side surfaces of the first to fourth semiconductor chips 100, 200, 300, and 400. In an implementation, the molding member 600 may surround the side surfaces of the first to fourth semiconductor chips 100, 200, 300, and 400 and a side surface of the NCF, and may be formed so that the NCF is not exposed to the outside.

In an implementation, the molding member 600 may cover an upper surface of the fourth semiconductor chip 400. In an implementation, the molding member 600 may expose the upper surface of the fourth semiconductor chip 400 to the outside. In an implementation, the molding member 600 may be formed of, e.g., an epoxy molding compound (EMC).

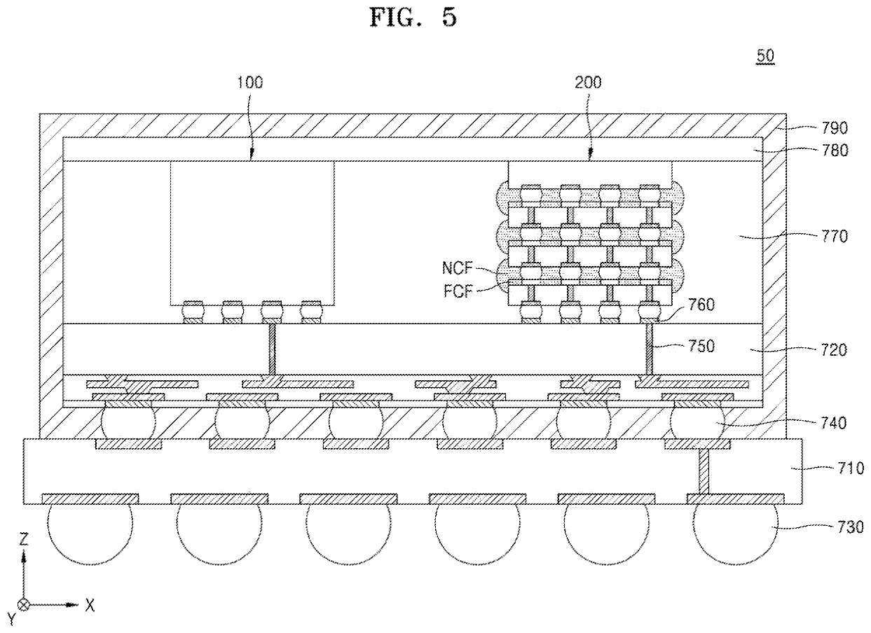

Referring to FIG. 5, the semiconductor package 50 may include a package substrate 710, an interposer 720 on the package substrate 710, and a first semiconductor chip 100 and a second semiconductor chip 200 on the interposer 720.

The package substrate 710 included in the semiconductor package 50 of the present embodiment may be formed based on a PCB, a wafer substrate, a ceramic substrate, a glass substrate, or the like.

An external connection terminal 730 may be on a lower surface of the package substrate 710. The semiconductor package 50 may be electrically connected to and mounted on a module board or a system board of an electronic product through the external connection terminal 730.

The interposer 720 may include an internal connection terminal 740 connected to a lower portion thereof. The internal connection terminal 740 may be electrically connected to the first and second semiconductor chips 100 and 200 through a through-electrode 750. In an implementation, a first bump pad 760 may be on an upper surface of the interposer 720.

In the semiconductor package 50 of the present embodiment, the first semiconductor chip 100 and the second semiconductor chip 200 may be mounted on the interposer 720. In addition, a molding member 770 may surround the first semiconductor chip 100 and the second semiconductor chip 200, and a heat dissipation member 780 may be on the molding member 770. In an implementation, the semiconductor package 50 may include an encapsulation 790 surrounding the interposer 720, the molding member 770, and the heat dissipation member 780.

The first semiconductor chip 100 may be a single logic chip and may be implemented as a microprocessor, a graphics processor, a signal processor, a network processor, a chipset, an audio codec, a video codec, an application processor, or a system-on-chip. The second semiconductor chip 200 may be an HBM chip in which a plurality of slices form a stack structure.

In the semiconductor package 50 of the present embodiment, an NCF and an FCF may include substantially the same or similar characteristics described above in the semiconductor package 10 among the plurality of slices.

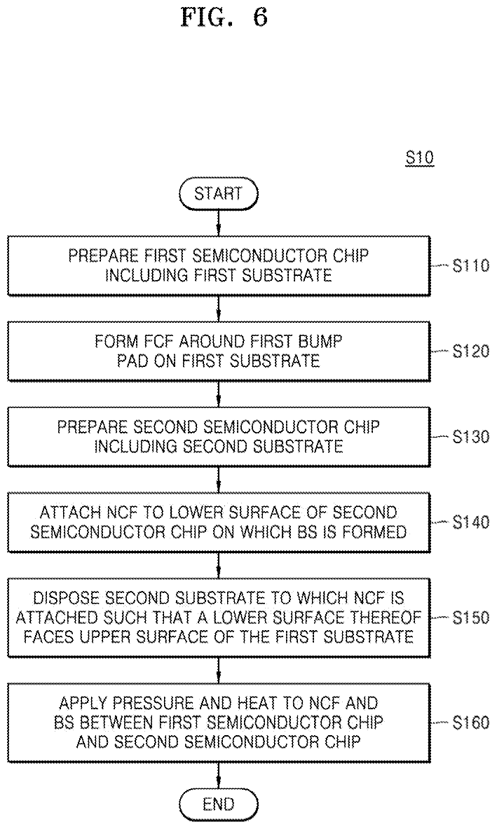

FIG. 6 is a flowchart of a method (S10) of manufacturing a semiconductor package according to an example embodiment.

Referring to FIG. 6, the method (S10) of manufacturing a semiconductor package may include process sequences of first to sixth operations (S110 to S160).

In cases where certain embodiments are otherwise practicable, a certain process sequence may be performed differently from a described sequence. For example, two processes described in succession may be performed substantially simultaneously or may be performed in an order opposite to a described order.

The method (S10) of manufacturing a semiconductor package may include a first operation (S110) of preparing a first semiconductor chip including a first substrate, a second operation (S120) of forming an FCF around a first bump pad on the first substrate; a third operation (S130) of preparing a second semiconductor chip including a second substrate, and a fourth operation (S140) of attaching an NCF to a lower surface of the second semiconductor chip on which the bump structure is formed, a fifth operation (S150) of disposing the second substrate to which the NCF is attached such that a lower surface thereof faces an upper surface of the first substrate, and a sixth operation (S160) of applying pressure and heat to the NCF and the bump structure.

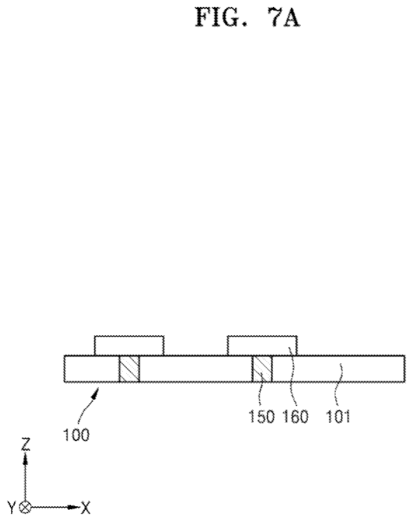

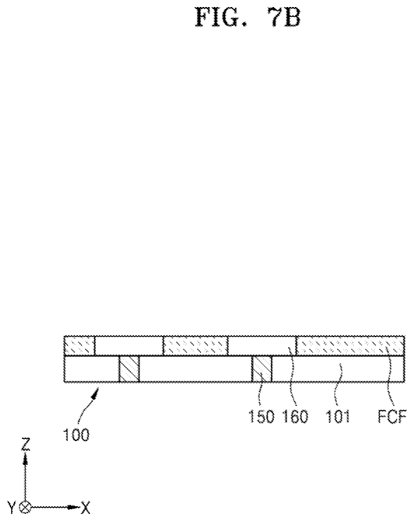

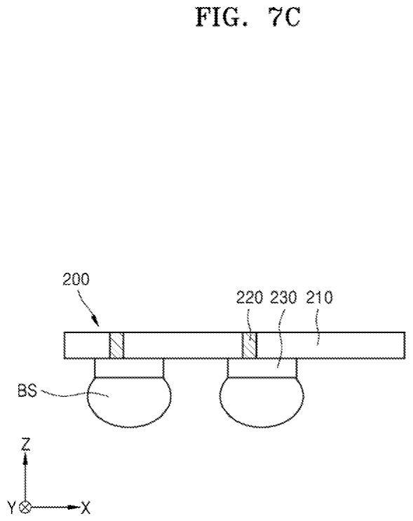

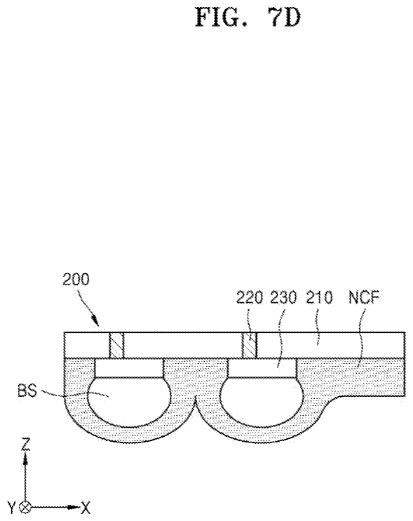

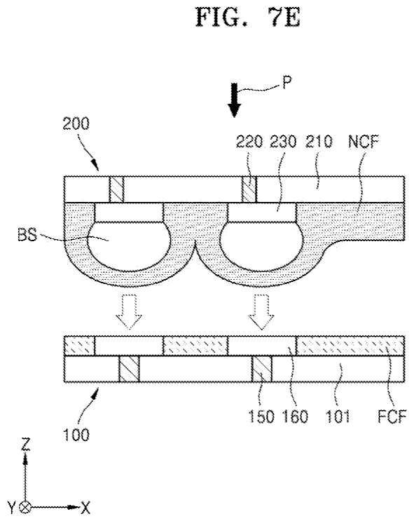

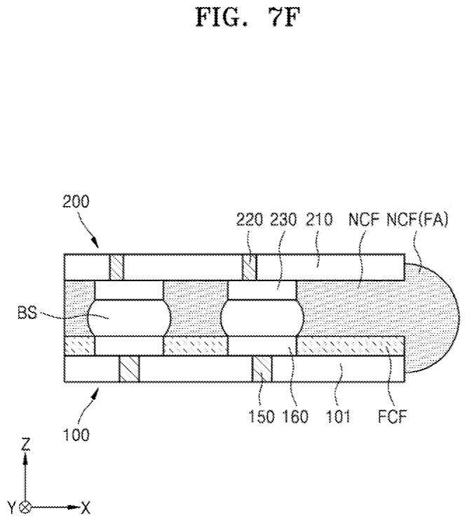

Technical characteristics of each of the first to sixth operations (S110 to S160) are described in detail with reference to FIGS. 7A to 7F below.

FIGS. 7A to 7F are cross-sectional views of stages in a method of manufacturing a semiconductor package according to an embodiment. In an embodiment, FIGS. 7A to 7F each show regions corresponding to FIG. 1B.

Referring to FIGS. 1A and 7A together, the first semiconductor chip 100 including the first substrate 101 to be below the semiconductor package may be prepared.

A plurality of first through-electrodes 150 may be formed in the first substrate 101. In an implementation, a method of forming the first through-electrodes 150 may include, e.g., a via-first method, a via-middle method, or a via-last method. In an implementation, in the via-last method, the first semiconductor device layer 110 and the first interconnection layer 120 may be formed on the lower surface 101B of the first substrate 101, and the first through-electrode 150 penetrating the first substrate 101 from the upper surface 101T to the lower surface 101B thereof may then be formed.

Next, the first bump pad 160 (electrically connected to the first through-electrode 150) may be formed. The first bump pad 160 may be formed on the upper surface 101T of the first substrate 101 so as to be electrically connected to the first through-electrode 150.

Referring to FIGS. 1A and 7B together, the FCF may be formed around the first bump pad 160 on the first substrate 101.

The FCF may expose the first bump pad 160 and may be formed to contact a side surface of the first bump pad 160. The FCF may be formed of an insulating material.

In an implementation, the FCF may be formed of, e.g., a polymer, benzocyclobutene, or a resin (e.g., a photosensitive polyimide). In an implementation, the FCF may be formed of silicon oxide or silicon nitride.

Referring to FIGS. 1A and 7C together, the second semiconductor chip 200 including the second substrate 201 to be disposed on the semiconductor package may be prepared.

The second semiconductor chip 200 may include the second substrate 201, the second semiconductor device layer 210, the second interconnection layer 220, the second bump pad 230, and the second through-electrode 250. The second semiconductor chip 200 may have characteristics that are the same as or similar to those of the first semiconductor chip 100.

Next, in order to form the BS on the second bump pad 230, a mask pattern having an opening exposing a portion of the second bump pad 230 may be formed on the second semiconductor device layer 210.

Next, a conductive material layer constituting the BS may be formed on the second bump pad 230 exposed through the opening of the mask pattern. In an implementation, the conductive material layer constituting the BS may include a pillar structure and a solder layer sequentially formed by a plating process.

Next, the mask pattern may be removed and a reflow process may be performed to form the BS having a ball shape.

Referring to FIGS. 1A and 7D together, the NCF may be attached to the lower surface of the second semiconductor chip 200 on which the BS has been formed.

The NCF may be attached to the lower surface of the second semiconductor chip 200 to cover all of the bump structures BS. In an implementation, the NCF may be attached to cover all of the second bump pads 230. In an implementation, the NCF may directly contact a portion of the second semiconductor device layer 210 in or on which the second bump pad 230 is not formed.

Referring to FIGS. 1A and 7E together, the lower surface 201B of the second substrate 201 (to which the NCF has been attached) may be aligned to face the upper surface 101T of the first substrate 101.

Due to pressure P applied to the second substrate 201, the second semiconductor chip 200 may be electrically connected to the first semiconductor chip 100 through the BS.

In an implementation, the FCF may be around the first bump pad 160 on the first substrate 101, and the thickness of the NCF may be reduced so that the amount of the NCF overflowing around the first and second semiconductor chips 100 and 200 may not be excessive after the first and second semiconductor chips 100 and 200 are bonded to each other

Referring to FIGS. 1A and 7F together, after the second semiconductor chip 200 is stacked on the first semiconductor chip 100, heat may be applied to the NCF and the BS between the first semiconductor chip 100 and the second semiconductor chip 200.

According to this process, the NCF may be cured so that the second semiconductor chip 200 may be firmly attached to the first semiconductor chip 100, and an intermetallic compound may be formed between the BS and the first bump pad 160, so that contact resistance may be lowered.

Through the manufacturing operations described above, the semiconductor package 10 including the first semiconductor chip 100, the second semiconductor chip 200, the NCF attaching the first and second semiconductor chips 100 and 200 to each other, and the FCF below the NCF may be manufactured.

Even if the pressure P applied to the second substrate 201 were reduced and the NCF were less compressed, unfilling may not occur, and the fillet area FA may protrude less or to a lesser degree to or at the periphery of the first and second semiconductor chips 100 and 200. Accordingly, the NCF may be prevented from excessively overflowing, and unfilling of the NCF may also be prevented.

In an implementation, the semiconductor package 10 may have an effect of providing high product reliability and high production efficiency.

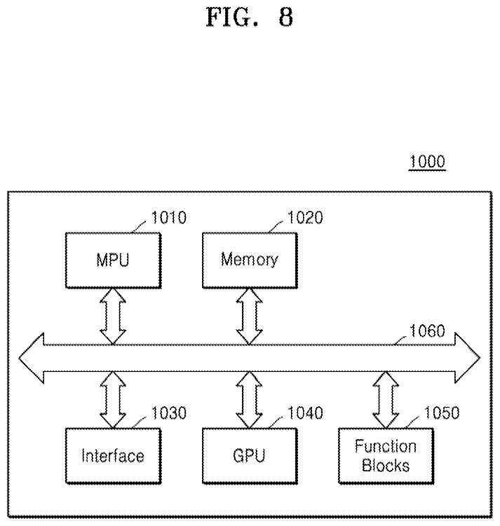

FIG. 8 is a view schematically illustrating a configuration of a semiconductor package 1000 according to embodiments.

Referring to FIG. 8, the semiconductor package 1000 may include a microprocessing unit (MPU) 1010, a memory 1020, an interface 1030, a graphics processing unit (GPU) 1040, function blocks 1050, and a bus 1060 connecting these components.

The semiconductor package 1000 may include both the MPU 1010 and the GPU 1040 or may include only one of the two.

The MPU 1010 may include a core and a cache. In an implementation, the GPU 1010 may include a multi-core. Each core of the multi-core may have the same or different performance. In addition, each core of the multi-core may be activated at the same time or may be activated at different times.

The memory 1020 may store a result of processing in the function blocks 1050 under the control of the MPU 1010. The interface 1030 may exchange information or signals with external devices. The GPU 1040 may perform graphic functions. In an implementation, the GPU 1040 may perform a video codec or process 3D graphics. The function blocks 1050 may perform various functions. In an implementation, when the semiconductor package 1000 is an application processor used in a mobile device, some of the function blocks 1050 may perform a communication function.

The semiconductor package 1000 may include any one of the semiconductor packages 10, 20, 30, 40, and 50 described above with reference to FIGS. 1A to 5.

One or more embodiments may provide a semiconductor package including a non-conductive film.

One or more embodiments may provide a semiconductor package including a non-conductive film for a stack of a semiconductor chip so as to realize high performance and large capacity along with miniaturization and weight reduction.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a first substrate including a first bump pad and a filling compensation film (FCF) around the first bump pad;
a second substrate facing the first substrate and including a second bump pad;
a bump structure (BS) in contact with the first bump pad and the second bump pad; and
a non-conductive film (NCF) surrounding the BS and between the first substrate and the second substrate,
wherein the NCF covers an upper surface and an edge of the FCF.

2. The semiconductor package as claimed in claim 1, wherein a level of an upper surface of the FCF is higher than a level of the upper surface of the first bump pad.

3. The semiconductor package as claimed in claim 2, wherein a lower portion of the BS is in contact with a sidewall of the FCF.

4. The semiconductor package as claimed in claim 1, wherein the edge of the FCF is coplanar with an edge of the second substrate in a vertical direction.

5. The semiconductor package as claimed in claim 4, wherein a width of a fillet area of the NCF protruding externally from the edge of the FCF and the edge of the second substrate in a horizontal direction is about 100 μm or less.

6. The semiconductor package as claimed in claim 1, wherein:
the FCF has a first thickness, and
the NCF has a second thickness, the second thickness being greater than the first thickness.

7. The semiconductor package as claimed in claim 1, wherein:
a sidewall of the first bump pad is in contact with the FCF, and
a sidewall of the second bump pad is in contact with the NCF.

8. The semiconductor package as claimed in claim 7, wherein:
the NCF includes an adhesive resin and a flux, and
the FCF includes a silicon insulating material or a polymer insulating material.

9. The semiconductor package as claimed in claim 1, further comprising:
a first through-electrode penetrating through the first substrate; and
a second through-electrode penetrating through the second substrate,
wherein:
a surface of the first substrate on which the first bump pad is disposed is an inactive surface, and
a surface of the second substrate on which the second bump pad is disposed is an active surface.

10. The semiconductor package as claimed in claim 9, further comprising one or more additional substrates stacked on the second substrate,
wherein the FCF and the NCF are between the second substrate and one of the one or more additional substrates and between adjacent ones of the one or more additional substrates.

11. A semiconductor package, comprising:
a base substrate;
semiconductor chips mounted on the base substrate, stacked in a direction perpendicular to an upper surface of the base substrate, and including a through-electrode therein; and
a connection layer between the base substrate and one of the semiconductor chips and between adjacent ones of the semiconductor chips, the connection layer including a filling compensation film (FCF) and a non-conductive film (NCF) covering the FCF.

12. The semiconductor package as claimed in claim 11, wherein the NCF covers an upper surface and an edge of the FCF.

13. The semiconductor package as claimed in claim 12, wherein:
the base substrate has a first width in a horizontal direction,
the semiconductor chips each have a second width, the second width being less than the first width, and
the NCF covers a portion of the upper surface of the base substrate.

14. The semiconductor package as claimed in claim 11, wherein a width of a fillet area of the NCF protruding externally from edges of the semiconductor chips in a horizontal direction is about 100 μm or less.

15. The semiconductor package as claimed in claim 11, wherein the base substrate is a printed circuit board (PCB), an interposer, or a buffer chip.

16. A semiconductor package, comprising:
a base substrate;
a first semiconductor chip including a first bump pad mounted on the base substrate and a filling compensation film (FCF) around the first bump pad, the first bump pad being connected to a first through-electrode;
a second semiconductor chip stacked on the first semiconductor chip and including a second bump pad connected to a second through-electrode;
a bump structure (BS) in contact with the first bump pad and the second bump pad;
a non-conductive film (NCF) surrounding the BS and between the first semiconductor chip and the second semiconductor chip; and
a molding member covering the base substrate, the first semiconductor chip, and the second semiconductor chip,
wherein the NCF covers an upper surface and an edge of the FCF.

17. The semiconductor package as claimed in claim 16, wherein:
a level of an upper surface of the FCF is higher than a level of the upper surface of the first bump pad, and
a lower portion of the BS is in contact with a sidewall of the FCF.

18. The semiconductor package as claimed in claim 16, wherein:
a width of a fillet area of the NCF protruding externally from the edge of the FCF and an edge of the second semiconductor chip in a horizontal direction is about 100 μm or less, and
the fillet area is covered with the molding member.

19. The semiconductor package as claimed in claim 16, wherein the FCF and the NCF are also between the base substrate and the first semiconductor chip.

20. The semiconductor package as claimed in claim 19, wherein:
the base substrate has a first width in a horizontal direction,
each of the first semiconductor chip and the second semiconductor chip has a second width, the second width being less than the first width, and
the NCF covers a portion of an upper surface of the base substrate.
